(19) United States
(12) Patent Application Publication
(10) Pub. No.: US 2016/0365253 A1
(43) Pub. Date: Dec. 15, 2016

(54) SYSTEM AND METHOD FOR CHEMICAL MECHANICAL PLANARIZATION PROCESS PREDICTION AND OPTIMIZATION

(71) Applicant: Macronix International Co., Ltd., Hsinchu (TW)

(72) Inventors: Kuang-Wei CHEN, Hsinchu City (TW); Chun-Fu CHEN, Taipei City (TW); Tuung LUOH, Taipei City (TW)

(73) Assignee: Macronix International Co., Ltd.

(21) Appl. No.: 14/950,899

(22) Filed: Nov. 24, 2015

Related U.S. Application Data
(60) Provisional application No. 62/173,131, filed on Jun. 9, 2015.

(51) Int. Cl. H01L 21/3105; H01L 29/06; H01L 21/762; G06F 17/50; H01L 21/66

(52) U.S. Cl. CPC H01L 21/31055; G06F 17/5068; H01L 22/10; H01L 21/76224; H01L 29/0649; G06F 2217/12

(57) ABSTRACT

A system for processing a semiconductor wafer includes a database configured to store data including relationships between device pattern characteristics, chemical mechanical polishing (CMP) conditions, and CMP performance, a data analyzer configured to predict performance of a CMP process to be performed on a wafer based on wafer design data and the relationships included in the database, and an output device configured to output the predicted performance of the CMP process.

### CROSS-REFERENCE TO RELATED APPLICATION

This application claims benefit of U.S. Provisional Application No. 62/173,131, filed on Jun. 9, 2015, the disclosure of which is incorporated herein by reference in its entirety.

### FIELD OF THE DISCLOSURE

The present disclosure relates to a system and a method for chemical mechanical planarization process prediction and optimization.

### BACKGROUND

Chemical Mechanical Planarization (CMP) has become a mainstream process in the semiconductor industry. It is a process for generating a flat and smooth surface at several critical steps in semiconductor manufacturing processes. The performance of the CMP process is influenced by topography characteristics of a semiconductor wafer to be processed, line/space width of patterns on the semiconductor wafer, pattern density, polish slurry chemistry, rotation speed of the semiconductor wafer with respect to a polishing pad, the type of the polishing pad, and force/pressure of the polishing pad with respect to the semiconductor wafer, etc. However, as semiconductor devices continue shrinking, it becomes more challenging to achieve planarization by using the CMP process.

### SUMMARY

According to an embodiment of the disclosure, a system for processing a semiconductor wafer includes a database configured to store data including relationships between device pattern characteristics, chemical mechanical polishing (CMP) conditions, and CMP performance, a data analyzer configured to predict performance of a CMP process to be performed on a wafer based on wafer design data and the relationships included in the database, and an output device configured to output the predicted performance of the CMP process.

According to another embodiment of the disclosure, a method for processing a semiconductor wafer includes establishing a database including relationships between pattern characteristics, chemical mechanical polishing (CMP) conditions, and CMP performance, predicting performance of a CMP process to be performed on a wafer based on wafer design data and the relationships included in the database, and outputting the predicted performance of the CMP process.

According to still another embodiment of the disclosure, a semiconductor device includes a substrate, a plurality of protrusions formed on the substrate and spaced apart from each other, a plurality of first material layers formed on portions of side surfaces of the plurality of protrusions, exposing portions of each of the protrusions, a plurality of stop layers formed on side surfaces of the first material layers, and a plurality of second material layers respectively formed between adjacent ones of the protrusions. A height of an exposed portion of a first protrusion on one portion of the substrate is the same as a height of an exposed portion of a second protrusion disposed on another portion of the substrate.

The accompanying drawings, which are incorporated in and constitute a part of this application, illustrate disclosed embodiments and, together with the description, serve to explain the disclosed embodiments.

### BRIEF DESCRIPTION OF THE DRAWINGS

FIGS. 1A through 1E are cross-sectional views of a wafer in a shallow trench isolation (STI) chemical mechanical planarization (CMP) process.

FIG. 2A schematically illustrates a dishing issue that occurs in an STI CMP process.

FIG. 2B schematically illustrates an erosion issue that occurs in an STI CMP process.

FIG. 3 is a schematic diagram of a CMP process prediction and optimization system according to an embodiment of the disclosure.

FIG. 4 is a flowchart of a process of CMP process prediction and optimization according to an embodiment of the disclosure.

FIG. 5 is a flowchart of a process of establishing a CMP database according to an embodiment of the disclosure.

FIGS. 6A-6F illustrate examples of test patterns according to embodiments of the disclosure.

FIG. 7 is a graphical representation of a line width and pattern density distribution of test patterns that are formed on one or more test wafers, according to an embodiment of the disclosure.

FIG. 8A is a post-CMP surface profile of a wafer measured by an atomic force microscope (AFM), according to an embodiment of the disclosure.

FIG. 8B is a scanning electron microscope (SEM) image of a portion of a wafer resulting from performing a CMP process, according to an embodiment of the disclosure.

FIG. 9 is a graphical representation of a relationship between pattern density and remaining thickness of a stop layer at a particular location on a wafer in a particular CMP process condition, according to an embodiment of the disclosure.

FIG. 10 is a graphical representation of a relationship between pattern density and dishing amount at a particular location on a wafer at various over-polishing (O.P.) times, according to an embodiment of the disclosure.

FIG. 11 is a flowchart of a process of predicting CMP performance according to an embodiment of the disclosure.

FIG. 12 is a three-dimensional (3D) image illustrating wafer design data and predicted remaining thicknesses of stop layers on a wafer after a CMP process, according to an embodiment of the disclosure.

FIG. 13 is a flowchart of a process of optimizing a CMP process according to an embodiment of the disclosure.

FIG. 14 is a flow chart of a process of making adjustments to the data in a CMP database, according to an embodiment of the disclosure.

FIGS. 15A through 15C are cross-sectional views of a wafer in an inter-level dielectric (ILD) CMP process.

### DETAILED DESCRIPTION

Reference will now be made in detail to the present embodiments, examples of which are illustrated in the accompanying drawings. Wherever possible, the same reference numbers will be used throughout the drawings to refer to the same or like parts.

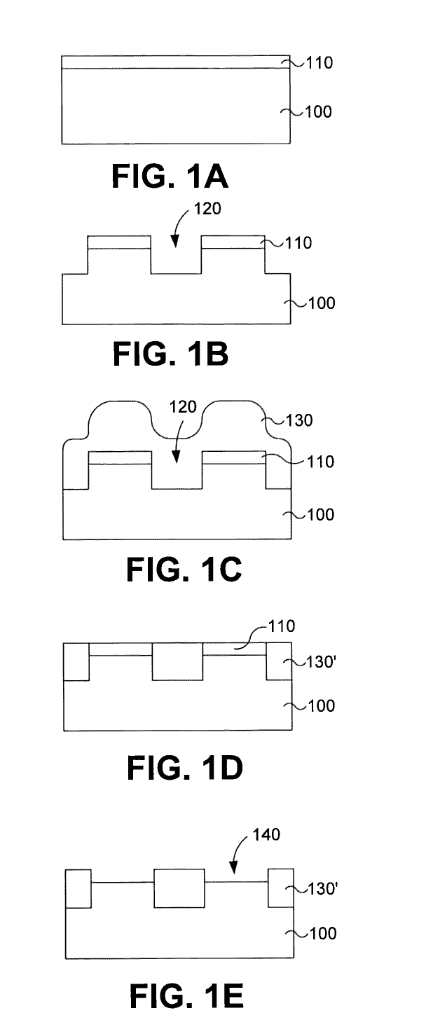

FIGS. 1A through 1E are cross-sectional views of a wafer in a shallow trench isolation (STI) CMP process. As illustrated in FIG. 1A, initially, a nitride layer 110 is formed on the entire surface of a substrate 100. Although not shown in FIG. 1A, substrate 100 may be formed with semiconductor device elements such as doped regions, polysilicon layers, thin oxide layers, etc. As illustrated in FIG. 1B, isolation trenches 120 are formed on substrate 100 including nitride layer 110. As illustrated in FIG. 1C, an oxide layer 130 is formed on the entire surface of substrate 100, filling isolation trenches 120. As illustrated in FIG. 1D, a CMP process is performed to polish oxide layer 130 by using nitride layer 110 as a stop layer. As a result, portions of oxide layer 130 that are disposed beyond the top surface of nitride layer 110 are removed, leaving oxide layers 130′ disposed in isolation trenches 120. As illustrated in FIG. 1E, after the CMP process, nitride layer 110 is removed by, for example, etching. Afterwards, devices (not shown) are formed in active areas 140, i.e., areas of substrate 100 between oxide layers 130′.

It is desirable to completely remove the portions of oxide layer 130 disposed on top of nitride layer 110 by the CMP process, so that nitride layer 110 can be completely removed, and devices can be formed in active areas 140. Therefore, normally, the CMP process is performed longer than necessary (so called “over-polish”) in order to ensure that the portions of oxide layer 130 disposed on top of nitride layer 110 across the entire substrate 100 are completely removed.

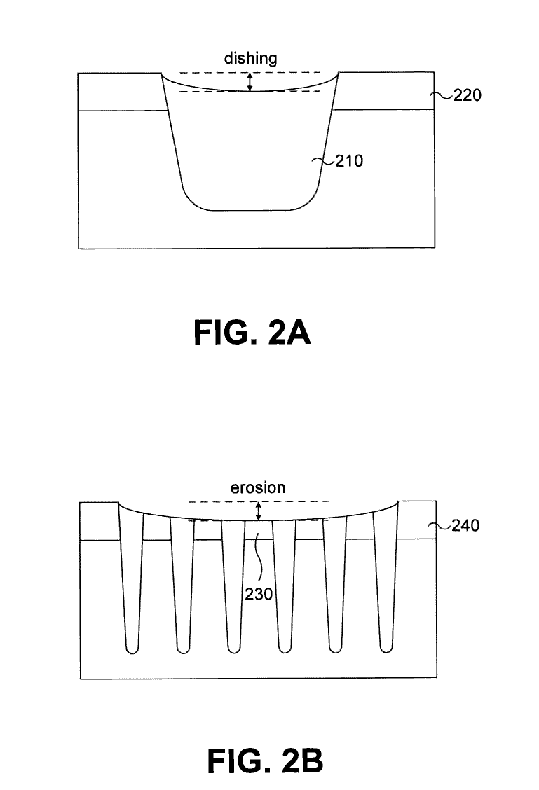

FIGS. 2A and 2B schematically illustrate two common issues that occur in an STI CMP process, i.e, dishing and erosion. As illustrated in FIG. 2A, dishing is defined as the loss of a top portion of an oxide layer 210 relative to the top level of a neighboring nitride layer 220. As illustrated in FIG. 2B, erosion is defined as the loss of a nitride layer 230 relative to the top level of nitride layer 240 in the neighboring area.

The amount of dishing and the amount of erosion are related to surface characteristics of the wafer to be polished. Wide trenches or open structures usually exacerbate the dishing issue, while dense trenches lead to more erosion. Nitride erosion exposes the underlying active devices, which can lead to device failure. On the other hand, oxide dishing can result in poor isolation.

According to an embodiment of the disclosure, results of experiments performed on test wafers are used for establishing a CMP database including relationships between wafer pattern characteristics, CMP conditions, and CMP performance on wafers. The wafer pattern characteristics include pattern densities, line widths, etc., of patterns to be formed on a wafer. The CMP conditions include process parameters of CMP processes, such as pad life, polish head down force, polish head rotation speed, slurry flow, over-polish time, over-polish amount, polish zone pressure, etc. The CMP performance on wafers is represented by post-CMP surface characteristics, such as dishing amount, erosion amount, and remaining thickness of a stop layer, etc., of wafers resulting from the CMP processes. Then, the CMP database is used to predict performance of a CMP process based on wafer design data.

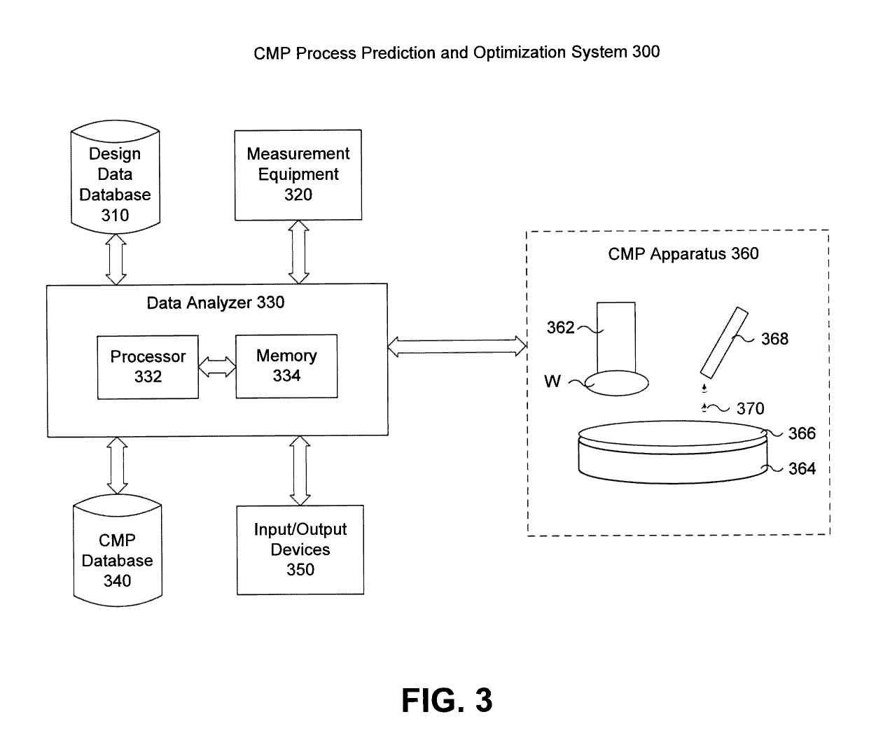

FIG. 3 is a schematic diagram of a CMP process prediction and optimization system 300 (hereinafter referred to as “system 300”) according to an embodiment of the disclosure. System 300 may include one or more hardware and/or software components configured to display, collect, store, analyze, evaluate, distribute, report, process, record, and/or sort information related to CMP process prediction and optimization. As illustrated in FIG. 3, system 300 includes a design data database 310, measurement equipment 320, a data analyzer 330, a CMP database 340, and input/output devices 350. System 300 also includes one or more CMP apparatus 360 that are communicatively coupled to data analyzer 330.

Design data database 310 is configured to store wafer design data, such as layout patterns of wafers to be processed by CMP apparatus 360. Design data database 310 is also configured to store design data of test wafers.

Measurement equipment 320 measures data regarding various surface characteristics of wafers before and after CMP processes, and transmits the measured data to data analyzer 330. Measurement equipment 320 includes one or more of an atomic force microscope (AFM), a scanning electron microscope (SEM), a transmission electron microscope (TEM), and other measurement devices that can be used to measure surface characteristics of wafers.

Data analyzer 330 includes a processor 332 and a memory 334. Processor 332 is configured to execute computer program instructions to perform various processes and methods consistent with certain disclosed embodiments. Memory 334 is configured to store various information and instructions to be executed by processor 332. Data analyzer 330 is communicatively coupled to design data database 310, measurement equipment 320, and CMP apparatus 360 to collect design data, surface characteristics data, and CMP conditions, and determine relationships between wafer pattern characteristics (i.e., pattern densities, line widths, etc.), CMP conditions, and CMP performance. Data analyzer 330 is also configured to predict CMP performance and/or generate optimized CMP conditions for a given set of design data based on the determined relationships.

CMP database 340 includes one or more software and/or hardware components that store, organize, sort, filter, and/or arrange data used by system 300 and/or processor 332. For example, CMP database 340 is communicatively coupled to data analyzer 330 to receive and store the relationships between wafer pattern characteristics, CMP conditions, and CMP performance determined by data analyzer 330.

Input/output devices 350 include one or more components configured to communicate information associated with system 300. For example, input/output devices 350 can include a console with an integrated keyboard and mouse to allow a user to input parameters associated with system 300 and/or data associated with CMP process prediction and optimization. Input/output devices 350 can also include one or more displays or other peripheral devices, such as, for example, printers, speaker systems, or any other suitable type of output devices for outputting CMP process prediction and/or optimization results generated by data analyzer 330.

CMP apparatus 360 includes one or more conventional components for performing a CMP process. For example, CMP apparatus 360 includes a polish head 362 for holding a wafer W and applying a polish head down force to wafer W, a rotation table 364, a polishing pad 366 disposed on rotation table 364, and a slurry supplier 368 for supplying polishing slurry 370 to polishing pad 366. CMP apparatus 360 is communicatively coupled to data analyzer 330 for receiving optimized process parameters and for performing a CMP process using the optimized process parameters. Although not illustrated, CMP apparatus 360 can include input devices for receiving user input regarding customized CMP conditions.

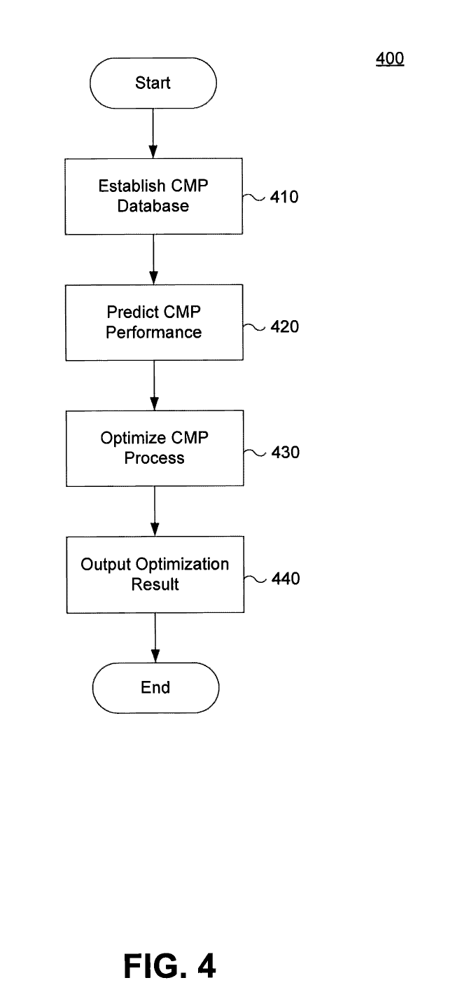

FIG. 4 is a flowchart of a process 400 of CMP process prediction and optimization according to an embodiment of the disclosure. Process 400 can be implemented by processor 332 of system 300. According to FIG. 4, initially, processor 332 establishes a CMP database (e.g., CMP database 340) based on experimental results performed on test wafers (step 410). CMP database 340 includes relationships between pattern characteristics, CMP conditions, and CMP performance. Processor 332 then predicts CMP performance for a set of data representing a design to be formed on a wafer based on the relationships in CMP database 340 (step 420). Processor 332 also optimizes a CMP process to be performed on the wafer based on the relationships in CMP database 340 (step 430). Processor 332 then outputs the optimization result (step 440). Then, process 400 ends. Upon completion of process 400, CMP apparatus 360 performs a CMP process based on the optimization result. Detailed explanation regarding each one of steps 410-430 is provided as follows.

Establishing CMP Database

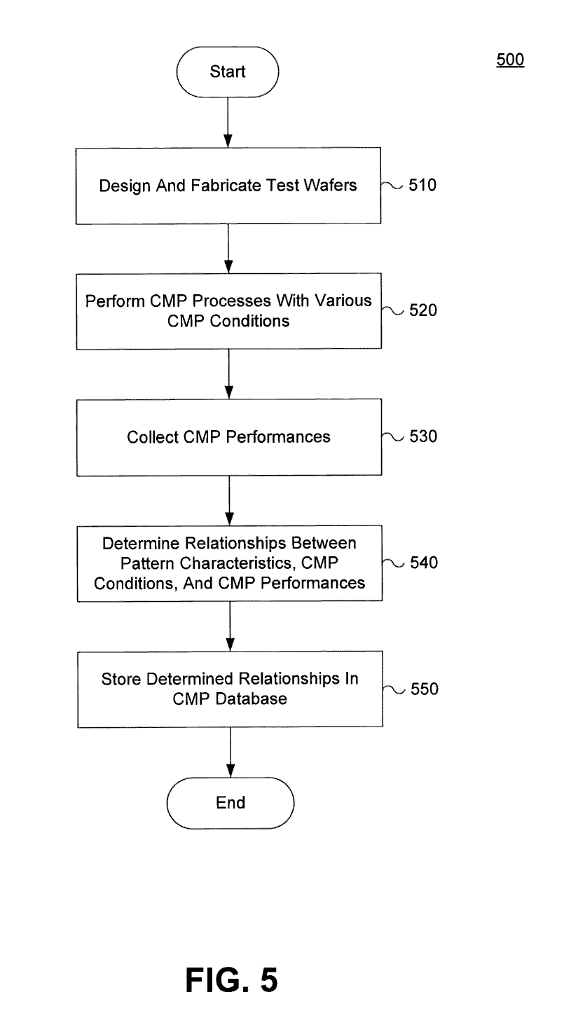

FIG. 5 is a flowchart of a process 500 of establishing a CMP database (step 410) according to an embodiment of the disclosure. Referring to FIG. 5, initially, one or more test wafers are designed and fabricated (step 510). CMP processes with various CMP conditions are performed on the test wafers (step 520). CMP performance is collected by measuring post-CMP surface characteristics of the test wafers resulting from the CMP processes (step 530). Then, the relationships between pattern characteristics, CMP conditions, and CMP performance are determined (step 540). Finally, the determined relationships are stored in a database, such as CMP database 340 illustrated in FIG. 3 (step 550).

In step 510, each one of the one or more test wafers are formed with test patterns having various pattern characteristics, i.e., various shapes, sizes, pattern densities, and line widths, etc. Specifically, each test wafer is formed with a substrate having test patterns in the form of step heights (e.g., substrate 100 in FIGS. 1B-1D), a stop layer (e.g., nitride layer 110 in FIGS. 1B-1D) disposed on the substrate, and a layer to be polished (e.g, oxide layer 130 in FIG. 1C).

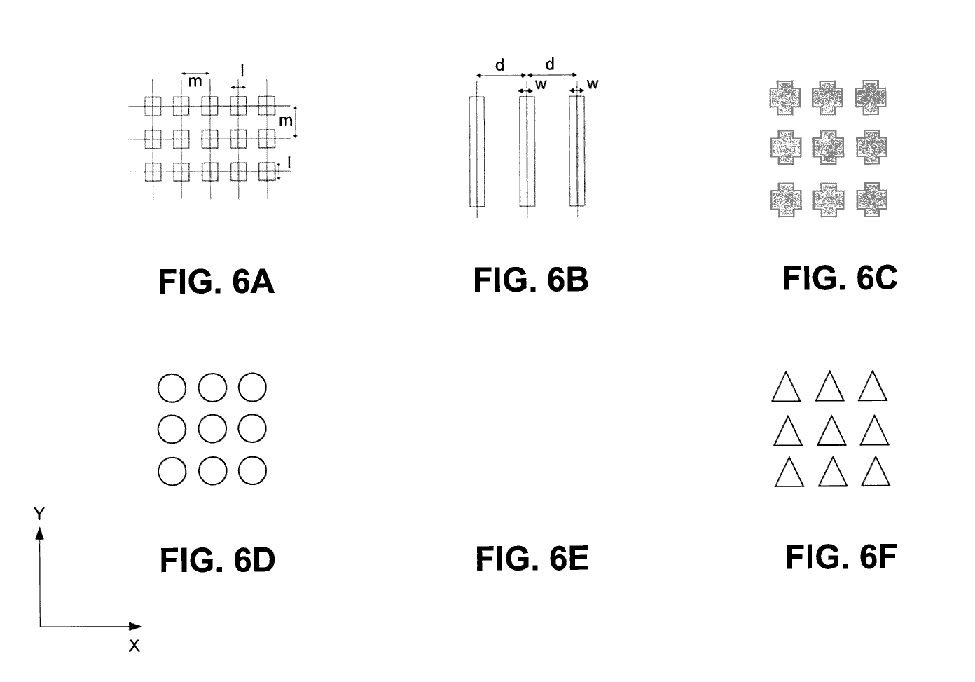

FIGS. 6A-6F illustrate non-limiting examples of test patterns according to embodiments of the disclosure. FIG. 6A illustrates a first test pattern including evenly distributed squares. The length of the sides of each square is l, and the distance between the center of each square and the center of an adjacent square is m. FIG. 6B illustrates a second test pattern including stripes that are equally spaced apart. The width of each stripe is w, and the distance between the center of each stripe and the center of an adjacent stripe is d. FIG. 6C illustrates a third test pattern including evenly distributed cross shapes. FIG. 6D illustrates a fourth test pattern including evenly distributed circular shapes. FIG. 6E illustrates a fifth test pattern including evenly distributed “L” shapes. FIG. 6F illustrates a sixth test pattern including evenly distributed triangular shapes.

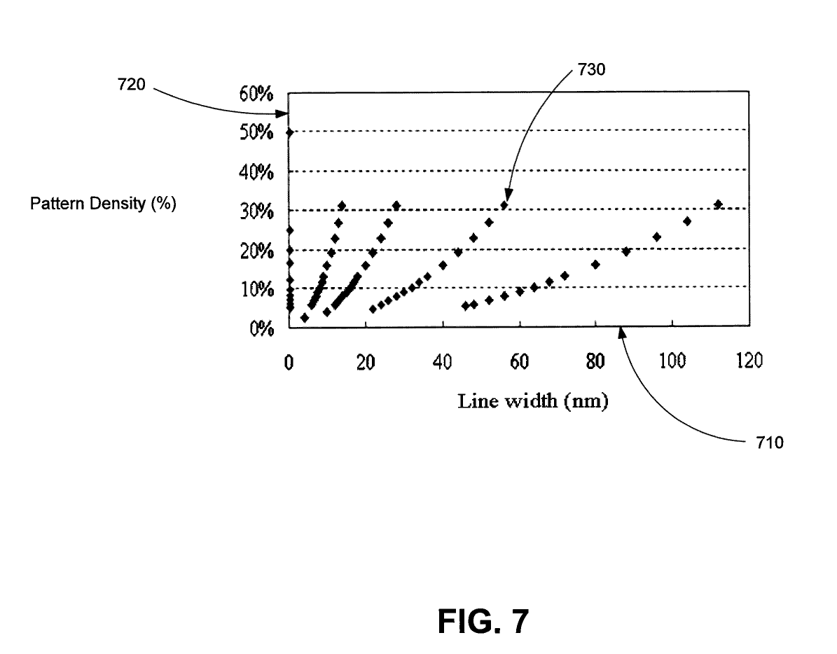

FIG. 7 is a graphical representation of a line width and pattern density distribution of test patterns that are formed on one or more test wafers, according to an embodiment of the disclosure. In the graph of FIG. 7, abscissa 710 represents a line width in nanometers (nm), and ordinate 720 represents a pattern density as a percentage (%). Each data point 730 in the graph of FIG. 7 represents a particular test pattern having a line width and a pattern density. As illustrated in FIG. 7, the pattern densities of the test patterns formed on the one or more test wafers range from about 5% to about 50%, and the line widths of the test patterns formed on the one or more test wafers range from about 5 nm to about 120 nm.

In some embodiments, a wafer is formed with a plurality of dies having substantially the same layout. Each die includes a plurality of test patterns having various shapes, densities, line widths, etc.

After test wafers are designed and fabricated, CMP processes with various CMP conditions are performed on the test wafers in step 520. The various CMP conditions can include at least one of pad life, polish head down force, rotation speed, slurry flow, over-polish (O.P.) time, over-polish (O.P.) amount, removal rate profile, zone pressure, etc. The pad life refers to the length of time that a polishing pad (e.g., polishing pad 366 illustrated in FIG. 3) has so far been used for polishing. Generally, using a polishing pad having a relatively short pad life results in a higher removal rate of the polished material than using a polishing pad having a relatively long pad life. The pad life of a polishing pad can be categorized as, for example, early stage, mid stage, or late stage. The polish head down force refers to a vertical force that is applied by a polish head (e.g., polish head 362 illustrated in FIG. 3) to a wafer (e.g., wafer W) held on the polish head toward a polishing pad (e.g., polishing pad 366). Generally, applying a relatively high polish head down force results in a higher removal rate than applying a relatively low polish head down force. The polish head down force can be categorized as, for example, a high down force or a low down force. The rotation speed refers to the relative speed between a rotation table (e.g., rotation table 364) and a wafer (e.g., wafer W). Generally, using a relatively high rotation speed results in a higher removal rate than using a relatively low rotation speed. The rotation speed can be categorized as, for example, high speed or low speed. The slurry flow refers to the flow rate of polishing slurry supplied from a slurry supplier (e.g., slurry supplier 368). The slurry flow can be categorized as, for example, high slurry flow rate or low slurry flow rate. The over-polish time refers to the length of time that a wafer has been over-polished. The over-polish time can be categorized as, for example, a high over-polish time or a low over-polish time. The over-polish amount refers to the amount of material that has been over-polished. The removal rate profile refers to the removal rate of the polished material at different locations on a wafer. The removal rate profile can be categorized as, for example, center fast (i.e., the removal rate of the polished material at the center of the wafer is faster than the removal rate of the polished material at the edge of the wafer), or edge fast (i.e., the removal rate of the polished material at the edge of the wafer is faster than the removal rate of the polished material at the center of the wafer). The zone pressure refers to the pressure applied to a particular zone on a back surface of the wafer to control the removal rate profile (i.e., the higher edge zone pressure will result in a faster removal rate profile at the edge of the wafer).

In some embodiments, each of the plurality of test wafers has performed thereon one of a plurality of CMP processes. Each of the plurality of CMP processes has different CMP process conditions, and at least two of the test wafers respectively have performed thereon different ones of the CMP processes. In addition, in some embodiments, at least one CMP process that is performed on a test wafer has various process conditions across the test wafer. For example, the polish head down force applied to a wafer or the over-polish amount can be different at different locations on the wafer.

After performing the CMP processes, CMP performance is collected in step 530. The CMP performance is collected by measuring post-CMP surface characteristics at multiple locations on the test wafers. The surface characteristics include remaining thickness of a stop layer (e.g., nitride layer 110 in FIG. 1D), the thickness of the polished layer (e.g., oxide layers 130′ in FIG. 1D), the dishing amount illustrated in FIG. 2A, and the erosion amount illustrated in FIG. 2B.

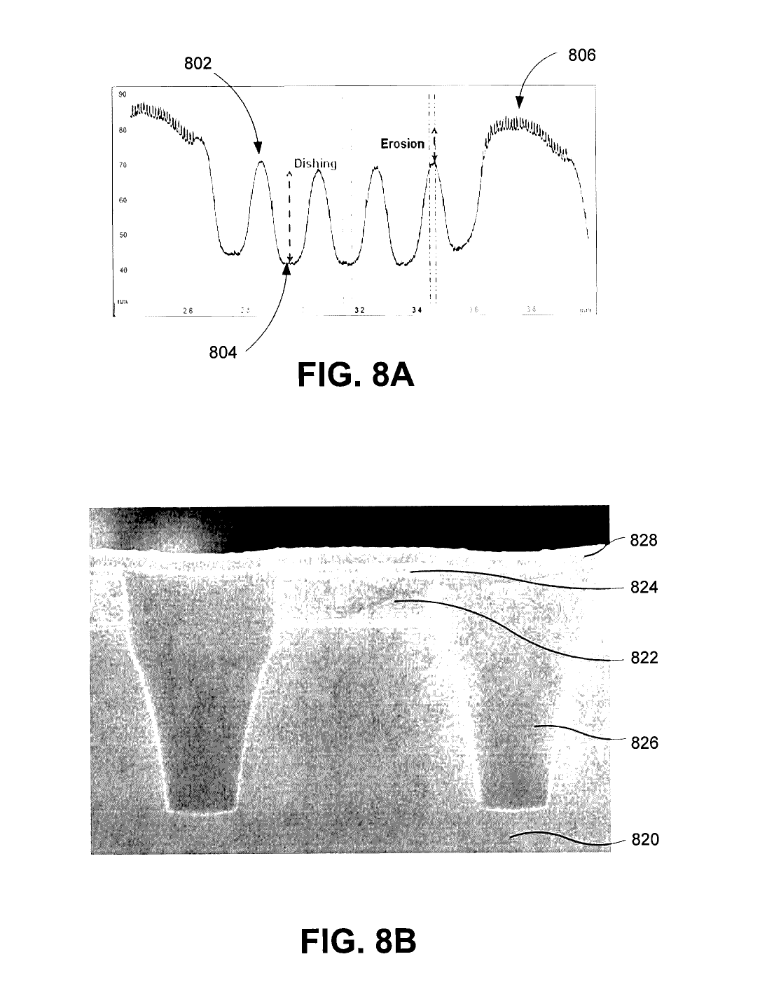

The dishing amount and the erosion amount can be obtained by measuring a post-CMP surface profile of a wafer using an AFM. FIG. 8A is a post-CMP surface profile of a wafer measured by an AFM, according to an embodiment of the disclosure. In FIG. 8A, peaks 802 indicate portions where stop layers exist, and valleys 804 indicate portions where polished layers exist. The dishing amount is measured as a vertical distance between one of valleys 804 and a peak 802 adjacent to the valley 804. The erosion amount is measured as a vertical distance between one of peaks 802 and a top level 806 of a neighboring area.

The remaining thicknesses of the stop layer and the polished layer are measured by using an SEM or TEM. FIG. 8B is an SEM image of a portion of a wafer resulting from performing a CMP process, according to an embodiment of the disclosure. The structure in FIG. 8B includes a silicon substrate 820, a first polysilicon layer 822 disposed on silicon substrate 820, a nitride stop layer 824 disposed on first polysilicon layer 822, silicon oxide layers 826 disposed on both sides of silicon substrate 820, first polysilicon layer 822, and nitride stop layer 824, and a second polysilicon layer 828 disposed on nitride stop layer 824 and silicon oxide layers 826. The thickness of the remaining nitride stop layer 824 is indicated by the thickness d denoted in FIG. 8B.

The measurements of post-CMP surface characteristics are performed at multiple locations on each test wafer, and at multiple locations within each die on the test wafers, so that the effect of pattern characteristics and CMP conditions on the CMP performance at various locations on test wafers can be observed.

After collecting the CMP performance, the relationships between pattern characteristics, CMP conditions, and CMP performance at various locations on a wafer are determined in step 540. The relationships may include a relationship between a particular pattern characteristic (e.g., pattern densities, line width, etc.) and a particular type of CMP performance (e.g., remaining thickness of stop layer, dishing amount, erosion amount, etc.) at a particular location on a wafer resulting from a CMP process having a particular CMP condition. The relationships can be determined based on the pattern characteristics, the CMP performance, and the various CMP conditions.

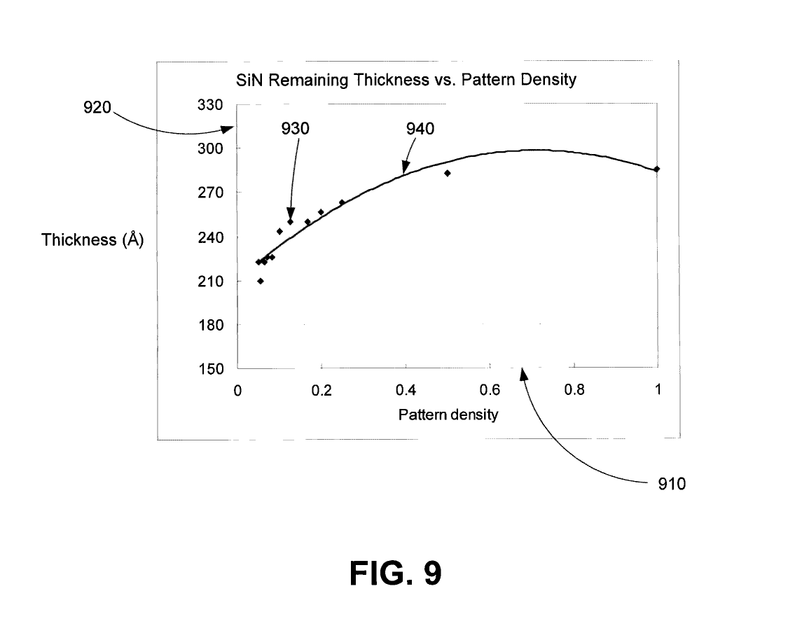

FIG. 9 is a graphical representation of a relationship between test pattern density and remaining thickness of a stop layer at a particular location on a wafer in a particular CMP process condition, according to an embodiment of the disclosure. In the graph of FIG. 9, abscissa 910 represents a pattern density, and ordinate 920 represents a stop layer thickness in angstroms (Å). Each data point 930 represents experimental data of pattern density of a test pattern formed on a test wafer and the corresponding remaining thickness of a silicon nitride (SiN) layer as a stop layer at the particular location on the test wafer. Line 940 represents a relationship between pattern density and remaining thickness of the SiN layer obtained by fitting the experimental data represented by data points 930. In this example, the remaining stop layer thickness increases with increasing pattern density.

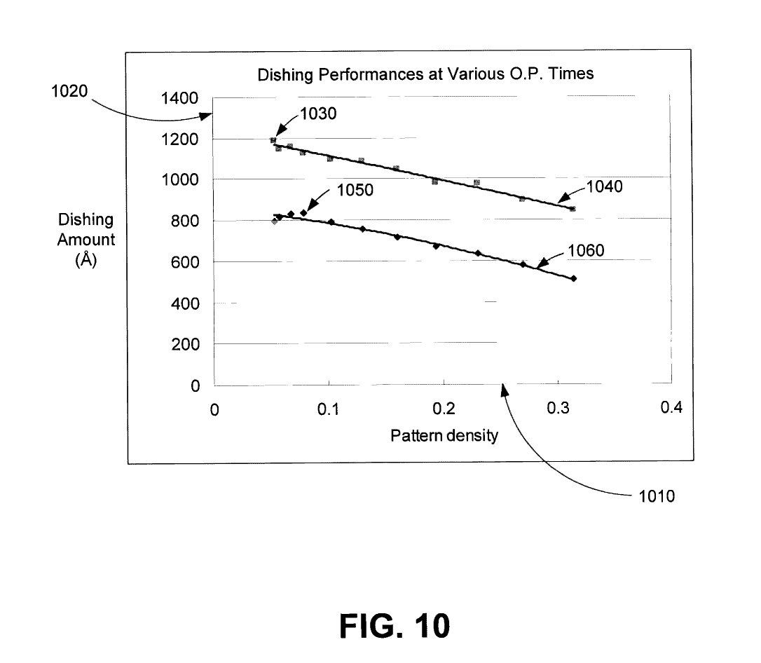

FIG. 10 is a graphical representation of the relationship between pattern density and dishing amount at a particular location on a wafer at various over-polishing (O.P.) times, according to an embodiment of the disclosure. In the graph of FIG. 10, abscissa 1010 represents a pattern density, and ordinate 1020 represents a dishing amount in angstroms (Å). Each data point 1030 represents experimental data of pattern density of a test pattern formed on a test wafer and the corresponding dishing amount at the particular location on the test wafer, at a relatively long over-polishing (O.P.) time. Line 1040 represents a relationship between pattern density and dishing amount at the relatively long O.P. time, obtained by fitting the experimental data represented by data points 1030. Each data point 1050 represents experimental data of pattern density of a test pattern formed on a test wafer and the corresponding dishing amount at the particular location on the test pattern, at a relatively short O.P. time. Line 1060 represents a relationship between pattern density and dishing amount at the relatively short O.P. time, obtained by fitting the experimental data represented by data points 1050. In this example, the dishing amount decreases with increasing pattern density. In addition, for the same pattern density, the dishing amount decreases with decreasing over-polishing time.

Predicting CMP Performance

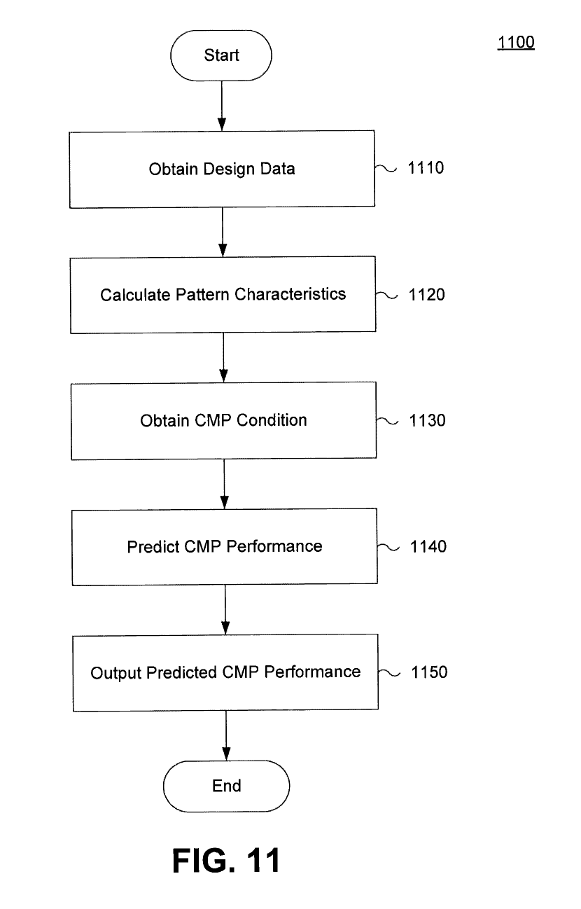

FIG. 11 is a flowchart of a process 1100 of predicting CMP performance (step 420) according to an embodiment of the disclosure. Process 1100 can be implemented by processor 332 of system 300. Referring to FIG. 11, initially, processor 332 obtains wafer design data regarding patterns to be formed on a wafer (step 1110). For example, processor 332 obtains the design data from design data database 310. As another example, processor 332 obtains the design data input by a user via input/output devices 350.

Then, processor 332 processes the design data to calculate pattern characteristics (e.g., pattern densities, line widths, etc.) of the design data (step 1120). Since the design data may vary across the entire wafer, the pattern characteristics also vary across the entire wafer. Therefore, processor 332 calculates the pattern characteristics at various locations on the wafer. In some embodiments, processor 332 outputs a map of pattern densities across the wafer.

Processor 332 also obtains a CMP condition (step 1130). The CMP condition includes a set of CMP process parameters such as pad life, polish head down force, rotation speed, slurry flow, over-polish (O.P.) time, over-polish (O.P.) amount, removal rate profile, and zone pressure, etc. The CMP condition obtained by processor 332 in step 1130 can be a default CMP condition pre-stored in memory 334 of data analyzer 330. Alternatively, processor 332 can communicate with CMP apparatus 360 to obtain the current settings of CMP apparatus 360 and determine the CMP condition based on the current settings of CMP apparatus 360. Still alternatively, processor 332 can receive a CMP condition input by a user via input/output devices 350.

Afterwards, processor 332 predicts CMP performance (e.g., dishing amount, erosion amount, and remaining thickness of a stop layer) at various locations on the wafer (step 1140). Processor 332 predicts the CMP performance based on the pattern characteristics calculated at step 1120, the CMP condition obtained at step 1130, and the relationships included in CMP database 340. For example, processor 332 calculates a remaining thickness of a SiN layer as a stop layer based on fitting result of line 940 described above. Since the pattern characteristics vary across the wafer, processor 332 determines the CMP performance at various locations on the wafer.

Finally, processor 332 outputs the predicted CMP performance (step 1150). For example, processor 332 outputs the predicted CMP performance via a display device or a printer included in input/output devices 350.

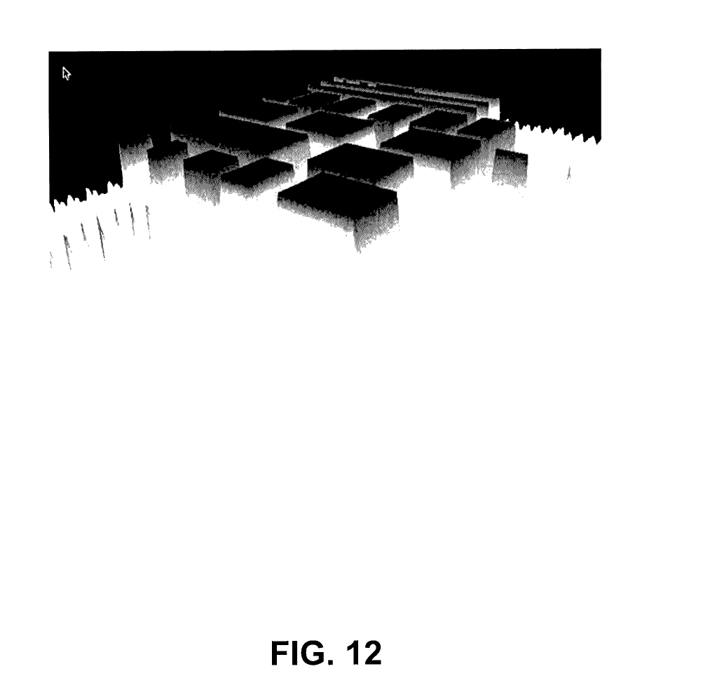

FIG. 12 is a three-dimensional (3D) image illustrating wafer design data and predicted remaining thicknesses of stop layers on a wafer after a CMP process, according to an embodiment of the disclosure. The 3D image is determined by processor 332. In the image of FIG. 12, darker colors represent thicker stop layers, and lighter colors represent thinner stop layers.

Optimizing CMP Process

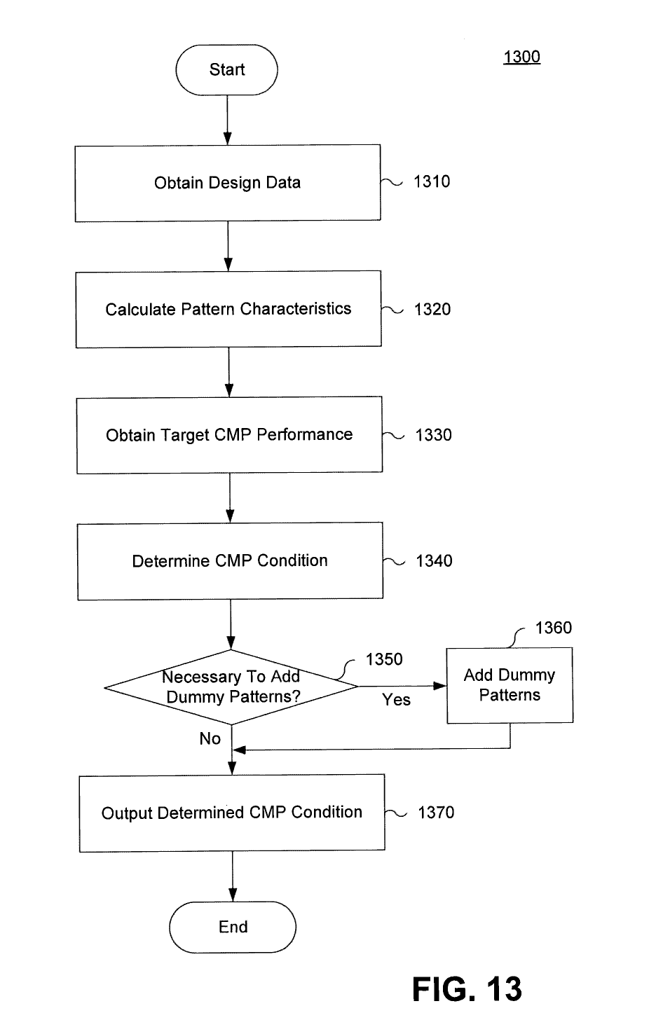

FIG. 13 is a flowchart of a process 1300 of optimizing a CMP process (step 430) according to an embodiment of the disclosure. Process 1300 can be implemented by processor 332 of system 300. Referring to FIG. 13, initially, processor 332 obtains wafer design data regarding a pattern to be formed on a wafer (step 1310). Processor 332 processes the design data to calculate pattern characteristics (e.g., pattern densities, line widths, etc.) of the design data (step 1320).

Processor 332 also obtains a target CMP performance (step 1330). The target CMP performance can include, for example, the dishing amount being less than a threshold dishing amount, the erosion amount being less than a threshold erosion amount, the remaining thickness of the stop layer being greater than a threshold thickness, or the dishing amount and the erosion amount being uniform across at least one die or the entire wafer, or a combination of two or more of the above targets. Processor 332 can obtain the target CMP performance from memory 334 of data analyzer 330, or from user input via input/output devices 350.

Processor 332 then determines a CMP condition in order to achieve the target CMP performance (step 1340). The CMP condition can include at least one of CMP process parameters such as pad life, polish head down force, rotation speed, slurry flow, over-polish (O.P.) time, over-polish (O.P.) amount, removal rate profile, zone pressure, etc. Processor 332 determines the CMP condition based on the pattern characteristics, the target CMP performance, and the relationships included in CMP database 340. Since the pattern characteristics vary across the wafer, processor 332 determines the CMP conditions for various locations on the wafer. For example, processor 332 may determine the polish zone pressure to be applied to one of a plurality of zones on a back surface of a wafer and try to balance the dishing and erosion performance within each die and/or within the entire wafer.

After determining the CMP condition, in one embodiment, processor 332 transmits the determined CMP conditions to CMP apparatus 360, such that CMP apparatus 360 can perform a CMP process according to the determined CMP conditions.

Alternatively, in another embodiment as illustrated in FIG. 13, processor 332 determines whether it is necessary to add dummy patterns in some risk areas on the wafer (step 1350). A risk area refers to an area on a wafer where the predicted dishing amount, erosion amount, or remaining thickness of stop layer is beyond an allowable range. Such risk area usually results from low pattern density in the area. Sometimes, the target CMP performance still cannot be achieved even with the CMP condition determined in step 1340. For example, if a process parameter included in the CMP condition determined in step 1340 is beyond a process constraint range of CMP apparatus 360, then the process parameter should be replaced by a closest allowable process parameter to be applied in the actual CMP process. Consequently, the target CMP performance cannot be achieved. In such case, processor 332 determines that it is necessary to add dummy patterns in the risk area in order to increase the pattern density in the risk area. For example, referring to FIG. 9, the remaining stop layer thickness increases with increasing pattern density. Accordingly, if processor 332 predicts that the remaining stop layer thickness will be smaller than the threshold thickness in the risk area, processor 332 determines to add dummy patterns in the risk area to increase the pattern density, such that the remaining stop layer thickness can be increased to reach the threshold thickness. As another example, referring to FIG. 10, the dishing amount decreases with increasing pattern density. Accordingly, if processor 332 predicts that the dishing amount will be greater than the threshold dishing amount, processor 332 determines to add dummy patterns in the risk area to increase the pattern density, such that the dishing amount can be reduced to the threshold dishing amount. As another example, processor 332 predicts the performance of the CMP process in different areas on the wafer based on the determined CMP condition, and compares the predicted performance with the target CMP performance in each area. If the difference between the predicted performance in any area and the target performance is beyond a tolerable range, processor 332 determines that it is necessary to add dummy patterns in that area.

If processor 332 determines that it is necessary to add the dummy patterns (step 1350: Yes), processor 332 modifies the design data to add dummy patterns in the corresponding risk areas (step 1360). Processor 332 then outputs the modified design data via input/output devices 350, to a photomask manufacturer, such that the photomask manufacturer can fabricate a photomask according to the modified design data. Then, processor 332 proceeds to step 1370.

If processor 332 determines that it is not necessary to add the dummy patterns (step 1350: No), processor 332 outputs the determined CMP condition (step 1370). Processor 332 may output a list of determined process parameters via a display or a printer included in input/output devices 350. Alternatively, processor 332 may directly output the determined CMP condition to CMP apparatus 360, so that CMP apparatus 360 can perform a CMP process by using the determined CMP condition. Then, process 1300 ends.

In some embodiments, processor 332 determines optimized CMP conditions based on predicted CMP performance. For example, processor 332 predicts the dishing and/or erosion amount at various locations across a wafer. Processor 332 then determines a zone pressure for each one of a plurality of zones on a back surface of the wafer during a CMP process, so that the dishing and/or erosion amounts at the various locations are substantially the same.

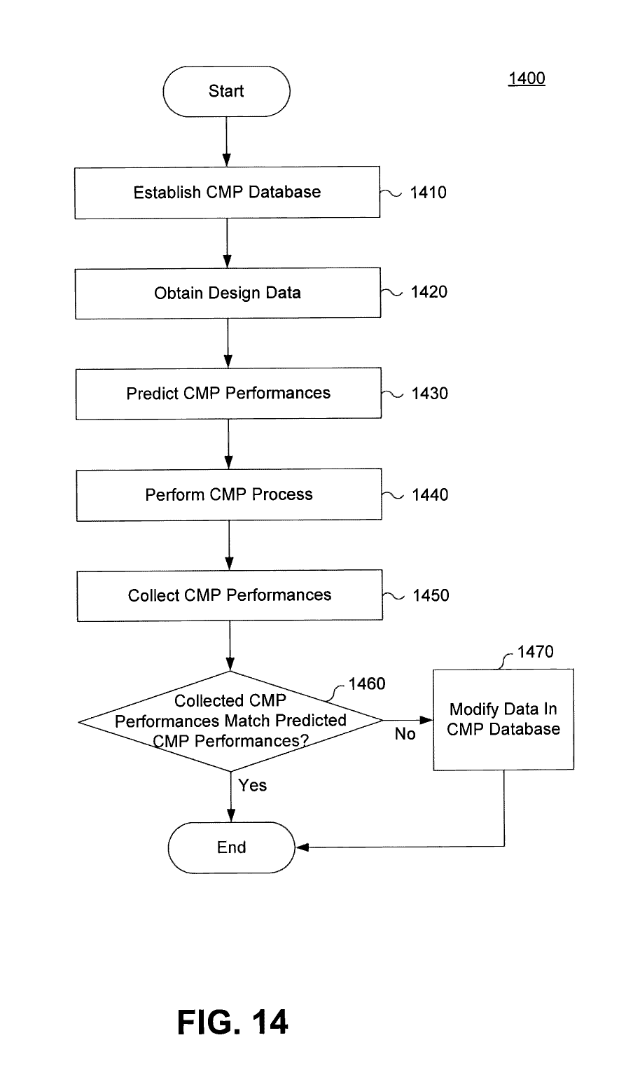

In some embodiments, after establishing CMP database 340 based on experimental data, processor 332 makes adjustments to the data in CMP database 340 based on CMP performance on real products. FIG. 14 is a flow chart of a process 1400 of making adjustments to the data in a CMP database, according to an embodiment of the disclosure. Process 1400 can be implemented by processor 332 of system 300. Initially, processor 332 establishes data in CMP database 340, the data including relationships between wafer pattern characteristics, CMP conditions, and CMP performance on wafers (step 1410). CMP database 340 can be established by using process 500 described above with respect to FIG. 5. Processor 332 obtains wafer design data regarding patterns to be formed on a wafer (step 1420). Then, processor 332 predicts CMP performance based on the design data (step 1430). Specifically, in step 1430, processor 332 processes the design data to calculate pattern characteristics of the design data, obtains a CMP condition, and then calculates the CMP performance based on the pattern characteristics, the CMP condition, and the relationships included in CMP database 340.

A CMP process is performed on the wafer by using the CMP condition obtained in step 1430 (step 1440). After the CMP process, CMP performance on the wafer is collected by, for example, measuring post-CMP surface characteristics at multiple locations on the wafer (step 1450).

Processor 332 compares the collected CMP performance with the predicted CMP performance, and determines whether the collected CMP performance matches the predicted CMP performance (step 1460). Processor 332 determines that the collected CMP performance matches the predicted CMP performance when the collected CMP performance is the same as the predicted CMP performance, or when the difference between the collected CMP performance and the predicted CMP performance is within a tolerable range.

If processor 332 determines that the collected CMP performance does not match the predicted CMP performance (step 1460: No), processor 332 modifies the data in CMP database 340 (step 1470). Specifically, processor 332 determines the relationships between pattern characteristics, CMP conditions, and CMP performance based on the collected CMP performance of the CMP process performed on the wafer, or a combination of the collected CMP performance and previously collected CMP performance of CMP processes performed on test wafers. Processor 332 then adjusts the data in CMP database 340 based on the determined relationships. Then process 1400 ends.

If processor 332 determines that the collected CMP performance matches the predicted CMP performance (step 1460: Yes), process 1400 ends. In some embodiments, processor 332 may repeat steps 1420 through 1470 several times until the collected CMP performance matches the predicted CMP performance.

The method of predicting and optimizing CMP performance according to the embodiments of the disclosure can be applied to CMP processes using stop layers. Examples of CMP processes using stop layer including a shallow trench isolation (STI) CMP process using a silicon nitride (SiN) layer as a stop layer, a polysilicon CMP process using a silicon oxide layer as a stop layer, a copper CMP process using a barrier layer as a stop layer, and an inter-level dielectrics (ILD) CMP process using a SiN layer as a stop layer.

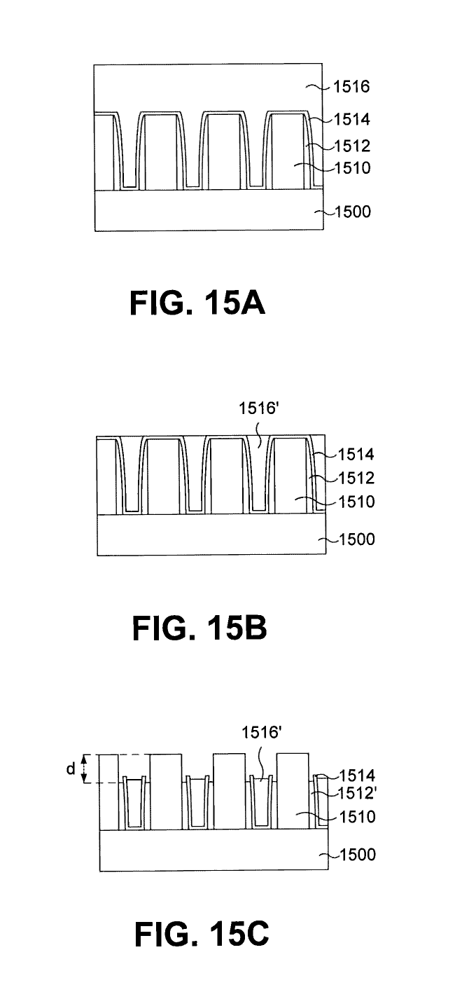

FIGS. 15A through 15C are cross-sectional views of a wafer in an ILD CMP process. As illustrated in FIG. 15A, a plurality of polysilicon layers 1510 in the form of protrusions are disposed on a substrate 1500. First thin oxide layers 1512 are formed on side walls of polysilicon layers. A nitride layer 1514 is formed on substrate 1500, covering polysilicon layer 1510, first oxide layers 1512, and portions of substrate 1500 exposed by polysilicon layers 1510 and first oxide layers 1512. A second oxide layer 1516 is formed on nitride layer 1514. Second oxide layer 1516 is thicker than first oxide layer 1512.

As illustrated in FIG. 15B, a CMP process is performed to polish second oxide layer 1516 by using nitride layer 1514 as a stop layer. As a result, portions of second oxide layer 1516 that are disposed beyond the top surface of nitride layer 1514 are removed, leaving only portions of second oxide layer 1516′ between polysilicon layers 1510.

As illustrated in FIG. 15C, in order to ensure that all of the portions of second oxide layer 1516 that are disposed beyond the top surface of nitride layer 1514 are removed, the CMP process continues for a certain period of time, i.e., over-polish time. As a result, the thickness of portions of second oxide layers 1516′ between polysilicon layers 1510, and the thickness of first oxide layers 1512′ between nitride layer 1514 and polysilicon layers 1510 are reduced, and portions of side surfaces of polysilicon layers 1510 are exposed. An exposed height d of polysilicon layer 1510 is defined as the vertical distance between a top surface of polysilicon layer 1510 and a top surface of the adjacent first oxide layer 1512′. The exposed height d of polysilicon layer 1510 directly affects the electrical resistance of polysilicon layer 1510.

If the ILD CMP process is not properly controlled to ensure that the CMP performance is uniform across the entire wafer or across each die, then the exposed height d of polysilicon layer 1510 will vary across the entire wafer or across each die. As a result, the resistance of polysilicon layers 1510 will vary across the entire wafer or across each die. On the other hand, by using the method according to the embodiment of the disclosure, the ILD CMP process can be controlled so that the CMP performance does not vary substantially across the wafer or across each die. As a result, the exposed height d of polysilicon layer 1510 does not vary substantially across the wafer or across each die. For example, the exposed height d of polysilicon layer 1510 disposed on one side of a wafer or a die is substantially the same as the exposed height d of polysilicon layer 1510 disposed on another side of the wafer or the die. Consequently, the performance of the semiconductor devices formed on the wafer can be improved.

A method according to the embodiments of the disclosure enables prediction of CMP performance (i.e., dishing and/or erosion amount) of CMP processes in new products based on pattern characteristics of wafer design data and pre-established relationships between pattern characteristics, CMP conditions, and CMP performance included in a database. The database is established based on measurement results of post-CMP surface characteristics of test wafers.

In addition, a method according to the embodiments of the disclosure enables optimization of CMP conditions based on wafer design data and the pre-established relationships. Therefore, the performance of CMP processes and the quality of the resulting semiconductor devices can be improved,

In addition, the methods according to the embodiments of the disclosure enable prediction of the CMP performance before photomasks are manufactured (i.e., mask tape-out), and modification of the wafer design data based on the prediction result to prevent defects formation in risk areas. Thus, desired CMP performance can be achieved on wafers with one or more risk areas.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system for processing a semiconductor wafer, comprising:
a database configured to store data including relationships between device pattern characteristics, chemical mechanical polishing (CMP) conditions, and CMP performance;
a data analyzer configured to predict performance of a CMP process to be performed on a wafer based on wafer design data and the relationships included in the database; and
an output device configured to output the predicted performance of the CMP process.

2. The system of claim 1, wherein the device pattern characteristics include at least one of pattern densities or line widths.

3. The system of claim 1, wherein the CMP conditions include at least one of pad life, polish head down force, rotation speed, slurry flow, over-polish (O.P.) time, over-polish (O.P.) amount, within wafer (WIW) range, and zone pressure.

4. The system of claim 1, wherein the CMP performance includes at least one of dishing amount, erosion amount, and remaining thickness of a stop layer.

5. The system of claim 1, wherein the relationships vary across the wafer.

6. The system of claim 1, wherein the relationships include a relationship between a particular pattern characteristic and a particular type of CMP performance at a particular location on a wafer resulting from a CMP process having a particular CMP condition.

7. The system of claim 1, wherein the data analyzer is further configured to determine optimized conditions of the CMP process to be performed on the wafer based on the wafer design data and the relationships included in the database.

8. The system of claim 7, further comprising a CMP apparatus configured to perform the CMP process on the wafer by using the optimized conditions.

9. The system of claim 1, wherein, when the data analyzer is configured to predict performance of a CMP process to be performed on a wafer based on wafer design data and the relationships included in the database, the data analyzer is configured to:
obtain the wafer design data;
calculate pattern characteristics of the wafer design data;
obtain CMP conditions of the CMP process to be performed on the wafer; and
predict the performance of the CMP process on the wafer based on the calculated pattern characteristics, the obtained CMP conditions, and the relationships included in the database.

10. The system of claim 1, wherein the data analyzer is further configured to:
determine whether it is necessary to add dummy patterns in at least one area in the wafer; and
in response to determining that it is necessary to add dummy patterns, modify wafer design data to add dummy patterns in the at least one area.

11. The system of claim 10, wherein the output device is further configured to output the modified wafer design data.

12. The system of claim 8, wherein the data analyzer is further configured to:
predict CMP performance of the CMP process on the wafer based on the wafer design data, the optimized conditions, and the relationships included in the database;
after performing the CMP process on the wafer by using the optimized conditions, collect CMP performance of the CMP process on the wafer, and determine whether the collected CMP performance matches the predicted CMP performance; and
in response to determining that the collected CMP performance does not match the predicted CMP performance, modify the relationships included in the database.

13. A method for processing a semiconductor wafer, comprising:
establishing a database including relationships between pattern characteristics, chemical mechanical polishing (CMP) conditions, and CMP performance;
predicting performance of a CMP process to be performed on a wafer based on wafer design data and the relationships included in the database; and
outputting the predicted performance of the CMP process.

14. The method of claim 13, wherein the establishing the database includes:
designing and fabricating a plurality of test wafers each including a plurality of test patterns in the form of step heights, the plurality of test patterns having various pattern characteristics;
performing, on each of the plurality of test wafers, one of a plurality of CMP processes having various CMP conditions;
collecting CMP performance of the CMP processes on the test wafers; and
determining relationships between pattern characteristics, CMP conditions, and CMP performance based on the pattern characteristics of the test patterns formed on the test wafers, the CMP conditions of the CMP processes performed on the test wafers, and the CMP performance of the CMP processes performed on the test wafers; and
storing the determined relationships in the CMP database.

15. The method of claim 14, wherein each of the plurality of test wafers includes a plurality of dies having substantially the same layout, and each of the plurality of dies includes the plurality of test patterns having various pattern characteristics.

16. The method of claim 14, further including:
performing, on a first test wafer, a first CMP process having a first CMP process condition; and
performing, on a second test wafer, a second CMP process having a second CMP process condition different from the first CMP process condition.

17. The method of claim 14, wherein each one the plurality of test patterns has at least various pattern densities or various line widths.

18. The method of claim 14, wherein the collecting CMP performance of the CMP processes on the test wafers includes measuring surface characteristics of the test wafers resulting from performing the CMP processes.

19. A semiconductor device, comprising:
a substrate;
a plurality of protrusions formed on the substrate and spaced apart from each other;
a plurality of first material layers formed on portions of side surfaces of the plurality of protrusions, exposing portions of each of the protrusions;
a plurality of stop layers formed on side surfaces of the first material layers; and
a plurality of second material layers respectively formed between adjacent ones of the protrusions;
wherein a height of an exposed portion of a first protrusion on one portion of the substrate is the same as a height of an exposed portion of a second protrusion disposed on another portion of the substrate.

20. The semiconductor device of claim 19, wherein
the plurality of protrusions are formed of polysilicon,
the plurality of stop layers are formed of silicon nitride,
the plurality of first material layers are formed of silicon oxide, and
the plurality of second material layers are formed of silicon oxide.
